(19) United States
(12) Patent Application Publication
(10) Pub. No.: US 2008/0213987 A1
(43) Pub. Date: Sep. 4, 2008

(54) Method of Fabricating a Sige Semiconductor Structure

(75) Inventors: Peter Deixler, Eindhoven (NL); Brian Wroblewski, Albuquerque, NM (US); Roy Colclaser, Albuquerque, NM (US)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONIN-KLIJKE PHILIPS ELECTRONICS, N.V., Eindhoven (NL)

(21) Appl. No.: 10/587,661

(22) PCT Filed: Oct. 24, 2004
(86) PCT No.: PCT/IB2004/052184

§ 371 Date: Oct. 30, 2007

Related U.S. Application Data
(60) Provisional application No. 60/514,448, filed on Oct. 24, 2003.

(51) Int. Cl. H01L 21/20

(52) U.S. Cl. 438/488; 257/E21.09

(57) ABSTRACT

A method of fabricating an integrated circuit includes providing a substrate and creating base-windows in a layer. The method also includes forming a monocrystalline SiGe base layer in each of the base layers, and polycrystalline SiGe elsewhere. Additionally, the method also includes forming a monocrystalline silicon layer over selectively exposed portions of the surface of the substrate. The integrated circuit beneficially includes silicon-based elements such as a lateral pnp transistor, a varactor, and a polysilicon transistor, which are formed on a common substrate with an npn SiGe bipolar transistor.

Lateral pnp (LPNP) and varactor diodes (Varicap or VCAP) are building blocks for radio frequency (RF) and other high frequency circuit design. The emitters of certain known silicon-based lateral pnp devices are formed by diffusion from a p-type polysilicon layer, which also serves as npn base-poly. This emitter is normally polysilicon, and lateral pnp ensures the high current gain, early voltage and frequency response necessary for advanced RF integrated circuits. Moreover, this technology has recently resulted in a polysilicon (poly) resistor based on the same p-type npn base polysilicon, showing excellent control and low-temperature coefficient.

Bipolar and complementary metal oxide semiconductor (BiCMOS) circuits are often used in high-speed/frequency devices, such as high speed analog circuits. These circuits may be employed, for example, in communications and computer applications. As is known, these BiCMOS circuits are beneficially fabricated on a common substrate. To meet this end, many Si-based BiCMOS processes feature high quality VCAPs, which are formed by diffusion from a p-type polysilicon into n-type monosilicon.

The use of materials other than silicon in BiCMOS and VCAP ICs has been explored. For example, silicon-germanium SiGe is exceedingly useful in high speed devices, due to its intrinsic carrier transport characteristics. In silicon BiCMOS technologies, the lateral PNP and Varicap areas are etched open in the same step as the bipolar NPN base. If a similar approach is used for SiGe BiCMOS, mono-crystalline SiGe will be deposited on both the NPN and Varicap/LPNP areas. However, the use of mono-crystalline SiGe at the emitter of the LPNP severely degrades the current gain of a pnp bipolar transistor, rendering it virtually unusable in this application. Additionally, boron diffusion, in mono-Si and especially in mono SiGe (in SiGe:C the carbon suppresses the diffusion almost 100%) is extremely slow, leading to insufficient depth of boron diffusion into the mono silicon.

As is well known, the depth of the boron diffusion from the base into the n-type material defines the electrical properties of the LPNP and VCAP. For example, in the case of the varicap, this translates into very shallow boron diffusion from the base poly into the mono-silicon. As a consequence the varicap junction between p-type diffusion and NWELL is not at the position desired for optimum tuning range. Moreover, the shallow junction results also in very high levels of reverse junction leakage currents, which are not acceptable for high-performance varicaps.

Hence, the known methods approach for integrating the LPNP and VCAP cannot be directly used in SiGe BICMOS, utilizing non-selective SiGe growth.

What is needed therefore is a method of fabricating a SiGe BICMOS structure, which overcomes at least the shortcomings of the methods described above.

In accordance with an example embodiment, a method of fabricating an integrated circuit includes providing a substrate; creating base-windows in a layer; forming a monocrystalline SiGe base layer in each of the base layers, and polycrystalline SiGe elsewhere; and forming a monocrystalline silicon layer over selectively exposed portions of the surface of the substrate.

The invention is best understood from the following detailed description when read with the accompanying drawing figures. It is emphasized that the various features are not necessarily drawn to scale. In fact, the dimensions may be arbitrarily increased or decreased for clarity of discussion.

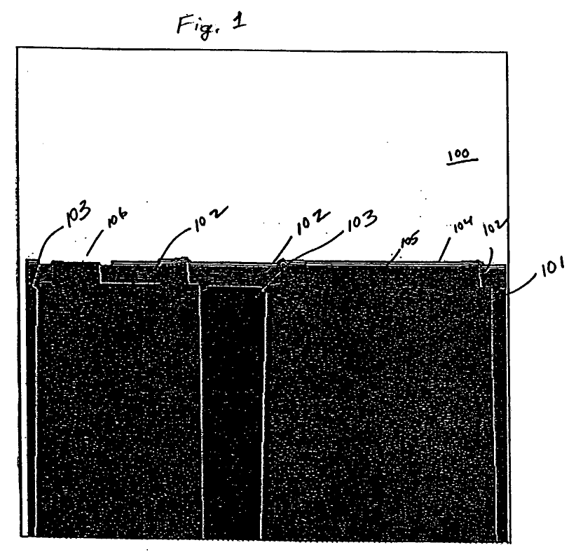

FIG. 1 shows a cross-sectional view of a semiconductor structure during a fabrication sequence of an example embodiment.

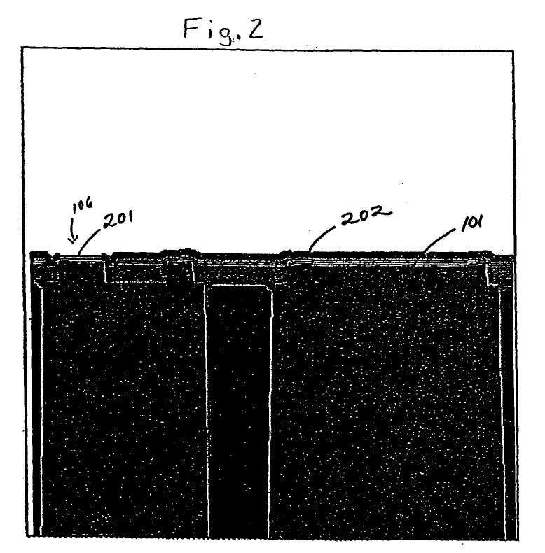

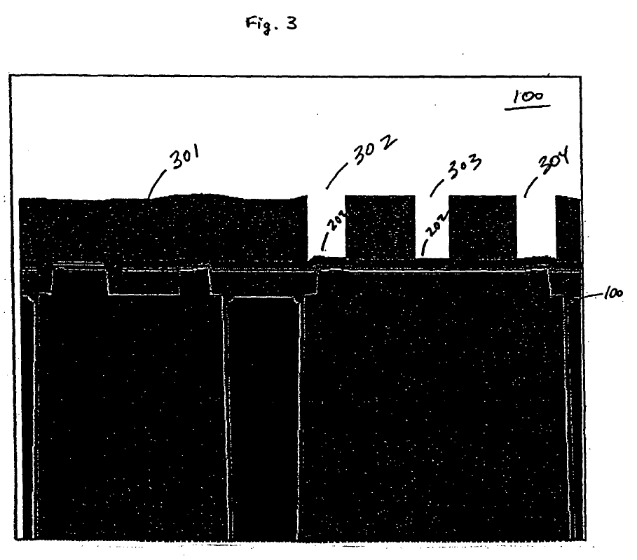

FIG. 2 shows a cross-sectional view of a semiconductor structure during a fabrication sequence of an example embodiment.

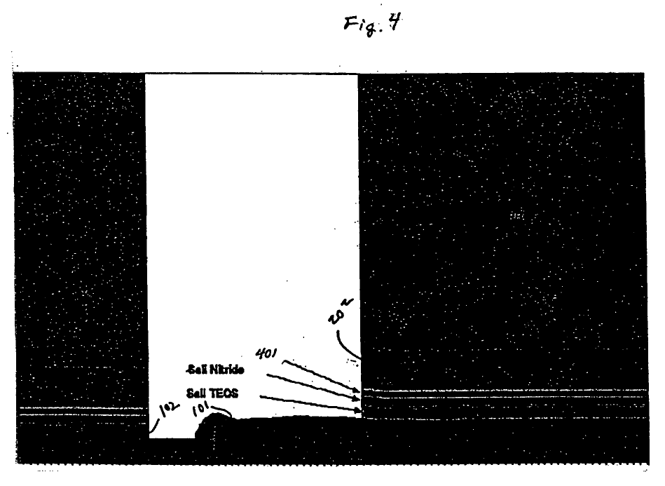

FIG. 3 shows a cross-sectional view of a semiconductor structure during a fabrication sequence of an example embodiment.

FIG. 4 shows a cross-sectional view of a semiconductor structure during a fabrication sequence of an example embodiment.

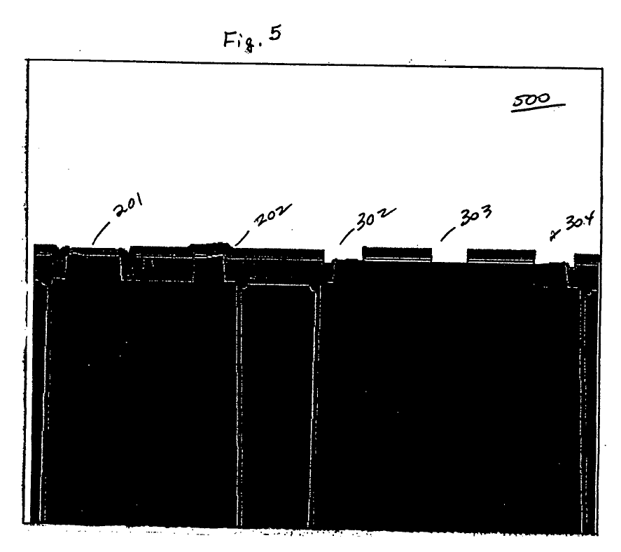

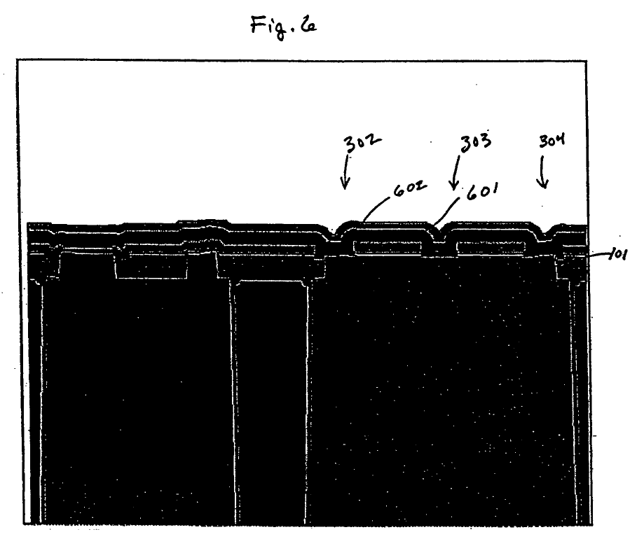

FIG. 5 shows a cross-sectional view of a semiconductor structure during a fabrication sequence of an example embodiment.

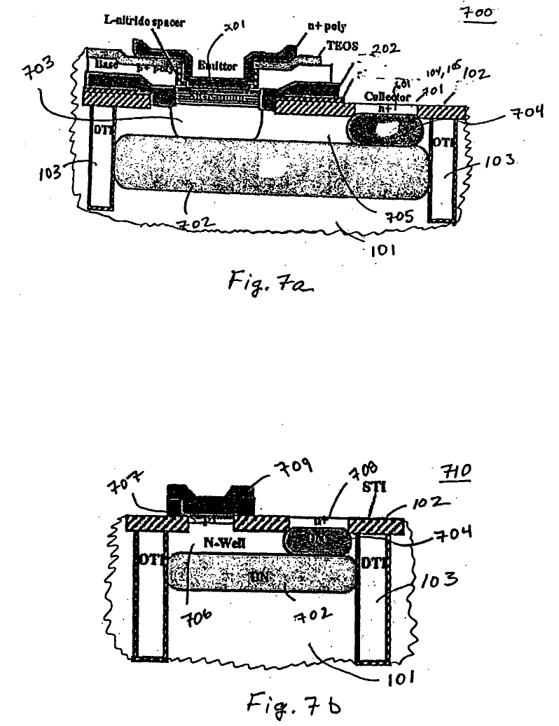

FIG. 6 shows a cross-sectional view of a semiconductor structure during a fabrication sequence of an example embodiment.

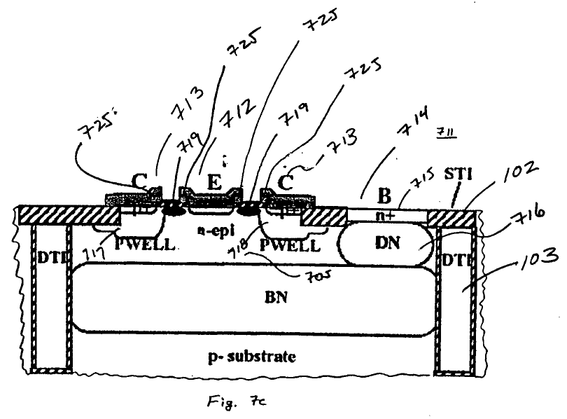

FIG. 7a shows a cross-sectional view of an npn bipolar transistor in accordance with an example embodiment.

FIG. 7b shows a cross-sectional view of a varactor diode in accordance with an example embodiment.

FIG. 7c shows a cross-sectional view of a lateral pnp transistor in accordance with an example embodiment.

FIG. 7d shows a cross-sectional view of a polysilicon resistor in accordance with an example embodiment.

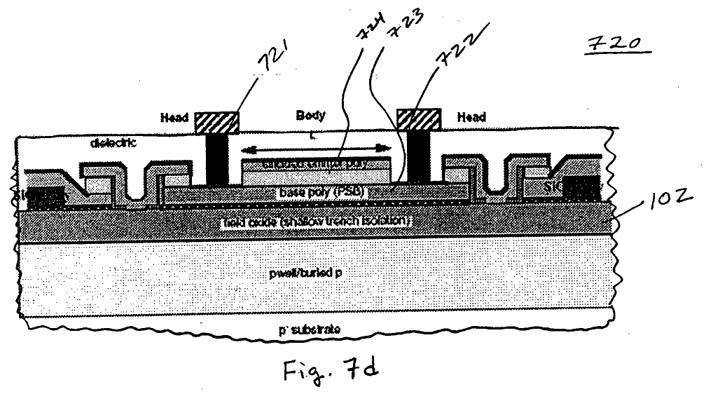

FIG. 8 shows a cross-sectional view of a semiconductor structure during a fabrication sequence of an example embodiment.

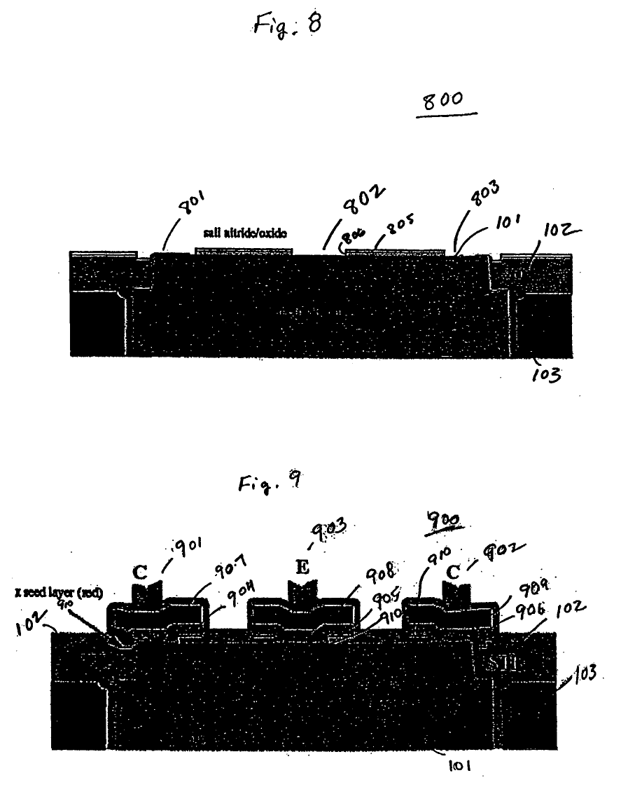

FIG. 9 shows a cross-sectional view of a semiconductor structure during a fabrication sequence of an example embodiment.

In the following detailed description, for purposes of explanation and not limitation, example embodiments disclosing specific details are set forth in order to provide a thorough understanding of the present invention. However, it will be apparent to one having ordinary skill in the art having had the benefit of the present disclosure, that the present invention may be practiced in other embodiments that depart from the specific details disclosed herein. Moreover, descriptions of well-known devices, methods and materials may be omitted so as to not obscure the description of the present invention. Wherever possible, like numerals refer to like features throughout.

Briefly, the methods of the example embodiments include fabricating a silicon lateral pnp transistor, a silicon varactor diode, or a polysilicon resistor, or a combination thereof, with the SiGe bipolar transistor on a common substrate. The processes of the example embodiments require only one additional masking step to form the lateral pnp, the varactor and the resistor.

FIG. 1 shows a semiconductor structure 100 during fabrication in accordance with an example embodiment. The structure ultimately will be formed into a SiGe npn/lateral pnp device. It is noted, of course that a slight modification of the connections to the lateral pnp may be made to form a varactor diode. Moreover, it is noted that MOS devices may be formed from the same structure 100, allowing for a BiCMOS structure. The MOS structure and certain fabrication details are described in U.S. Patent Application Publication 2003/0030244 A1 to Pruijmboom, et al., the disclosure of which is specifically incorporated herein by reference. Finally, the descriptions that follow illustrate an embodiment of the fabrication of a SiGe npn bipolar transistor, a lateral pnp Si transistor, a Si varicap and a p⁺ silcon resistor on a common substrate. It is noted that the fabrication concepts of the embodiments may certainly be applied to other polarity devices. For example, a SiGe pnp transistor may be desired. In such case the polarities of the Si-devices/elements described herein would be opposite to that described (e.g., the lateral Si transistor would be a lateral npn device.)

According to the example embodiment presently described, a substrate 101 is usefully n-doped monocrystalline silicon, and may be an epitaxially grown layer over another layer (not shown in FIG. 1). Likely, the substrate 101 is a p-type semiconductor (e.g., silicon) having an n-type epitaxial layer thereover. The substrate 101 has shallow trench isolation regions 102 and deep trench isolation regions 103. Alternatively, the substrate may be silicon on insulator (SOI). In addition to the use of SOI as the substrate, it is possible to implement the structure of example embodiments by transferring the semiconductor onto a glass substrate. In this example embodiment, the deep trench is optional. Moreover, the varicap can be used in a single ended differential configuration with multiple emitter fingers.

In the present example embodiment, the shallow and deep trench isolation regions 102,103 are fabricated using standard techniques and materials, such as TEOS SiO₂. Of course these materials and fabrication methods are merely illustrative, and other methods may be used.

Relatively thin insulator layers 104 and 105 are disposed over the substrate and trench isolation regions as shown. These layers are illustratively SiOₓ and Si₃N₄. The use of these layers will be apparent as the present description continues. Finally, an opening 106 is formed in the in the layers 104,105 by a standard masking and etching technique.

FIG. 2 shows the formation of monocrystalline SiGe 201 in the opening 106 at the surface of the substrate 101. The SiGe layer is fabricated by standard technique such as by low pressure chemical vapor deposition, ultra high vacuum CVD (UHCVD) or other suitable growth technique. The layer of SiGe formed on the monocrystalline silicon is a monocrystalline layer. However, elsewhere, the fabrication sequence of the SiGe forms a layer of polycrystalline SiGe 202. This polysilicon SiGe is useful in the formation of a lateral pnp device. To with, the use of monocrystalline SiGe in the emitter of the lateral pnp results in unacceptable degradation of the current gain.

The SiGe 201 may be used as an element (e.g., the base) of a bipolar transistor. To this end, as referenced above it is beneficial to provide SiGe electronic devices in integrated circuits, such as high speed/frequency devices. These devices include, but are not limited to, npn bipolar transistors for use in RF integrated circuits. Accordingly, the fabrication of monocrystalline SiGe layers as described in connection with example embodiments may be carried out to meet this end.

FIG. 3 shows a cross-sectional view of the substrate 101 after the formation of a masking layer 301, which has openings 302, 303 and 304 that locate the collector, emitter and collector, respectively, of a lateral pnp. Of course, a varactor diode could be located in this portion of the structure 100 as well. It is noted that the masking layer 301 is a standard mask formed by known deposition techniques, and the openings 302-304 are formed by etching techniques well-known in the art.

FIG. 4 shows opening 302 in enlarged view after the etching of the SiGe poly layer that was exposed in the opening. The etching of the poly SiGe is effected using a known technique, such as reactive ion etching. Moreover, standard etch chemistries are used for poly SiGe and nitride etching. The RIE stops in the oxide. The remaining oxide is removed by a known wet etching technique. In addition to the removal of the SiGe layer, a previously formed SiGe seed layer 401 as well as oxide layer 104 and nitride layer 105 are selectively etched, exposing the monocrystalline silicon substrate 101 and the shallow trench oxide 102 as shown.

FIG. 5 shows a structure 500 after the removal of the masking layer 301. The structure includes the openings 302-304 and the poly SiGe 202. The lateral pnp structure may be formed on the right-side of FIG. 5, and the npn structure may be formed on the left-side of FIG. 1.

After the removal of the masking layer 301 by known technique, a polysilicon layer 601 is formed over the surface of the substrate 101 as shown in FIG. 6. After the formation of the polysilicon layer 601, a TEOS layer 604 is formed as shown. The polysilicon layer 601 is disposed directly over the monocrystalline silicon of the substrate 101 via openings 302-304 as shown. Beneficially, the polysilicon 601 in the openings 302-304 may be used in the formation of the lateral pnp transistor and a varactor diode, if desired. To with, as is useful in the fabrication of bipolar devices, the polysilicon layer 601 may be selectively doped to form the lateral pnp emitter electrodes, and the varicap electrodes, as is desired. Illustratively, the dopant is Boron at a concentration of 1×10²¹atoms-cm⁻³. Arsenic could be used instead in the same concentration if a varicap is integrated in BiCMOS process with SiGe pnp rather than an npn transistor.

It is noted that an interfacial oxide layer 603 may be formed between the polysilicon 601 and the monocrystalline silicon substrate 101. This layer may be useful in setting the lateral pnp current gain and the varicap tuning ratio. Moreover, an intentionally grown interfacial oxide is formed in same furnace as polysilicon deposition. The current gain of the pnp is adjusted by adjusting the oxide. The pnp current gain can also be adjusted by changing the polysilicon thickness and the silicide type.

As may be useful, a p-type polysilicon resistor may be formed by removing a portion of the poly SiGe over the shallow trench isolation 102. The resistor may be defined with the emitter-opening etch, and can consist only of suitably doped poly-Si. Boron doped polysilicon resistors may be used due to their excellent control, good matching and low temperature coeffiecient. A well tailored p+ polysilicon resistor shows a positive temperature coefficient. This is complementary temperature behavior to the standard n+ gatepoly resistors (with a negative temp coefficient), and can be used in circuits to achieve close to zero temperature dependence of the resitance. The boron doped resistor can be placed on a shallow trench isolation 102, a deep trench isolation 103, or any dielectric stack.

FIGS. 7a-7d are cross-sectional views of various elements fabricated in accordance with example embodiments such as described above. These elements include bipolar transistors, varactor diodes and poly-resistors. While shown in four separate views, it is noted, of course that these elements are beneficially co-located on a common substrate.

FIG. 7a shows the resultant SiGe bipolar npn 700 of the fabrication sequence of the example embodiments described above. The npn transistor includes a collector 701, and a buried n-type layer 702. An n-type emitter region 703 is formed in an n-type epi-layer 705 that is formed over the p-type substrate 101. The collector region 704 is also n-type having been doped by known methods and materials.

An example embodiment of a varactor diode 710 fabricated using the techniques referenced above is shown in FIG. 7b. The varicap 710 is formed over a substrate 101, and includes an n-type well 702, a p⁺-type doped polysilicon contact 707 formed over an n-type well 706. An n⁺-type Poly SiGe contact 708 is fabricated per the exemplary methods described above. The p-type metallization is shown at 709. As is readily appreciated, the varicap 710 includes materials of, and is fabricated according to, the example embodiments described herein.

An example embodiment of a lateral pnp transistor 711 is shown in FIG. 7c. The semiconductor structure includes an emitter 712, and collectors 713. An n⁺ base 714 is formed during the processing sequence described above, and has a doped polysilicon region 715 disposed over a n-doped region 716. P-doped wells 717 and 718 for the collectors 713 are formed in the n-epi layer 705, which includes a buried n-layer 702. Lightly doped (LD) regions are formed as shown, and for reasons well-known in the art. Finally, tailor implants 719 are formed during the doping sequence as described herein.

It is noted that the patterning of the polysilicon electrodes for the varicap and the lateral pnp is done simulateously with the patterning of the npn base-layer stack. The npn base layer stack consists of base polysilicon layer with SiGe polycrystalline layer underneath. To enable patterning of NPN-base connection and lateral PNP electrodes at the same time, the layer stack to be removed must be identical in all chip areas. Consequently, the LPNP and varicap electrodes need to be larger than the opening from which the SiGe poly is removed during the LD-step. This may result in a certain portion of the SiGe poly remaining (shown at 725 in FIG. 7c).

A polysilicon resistor 720 of an example embodiment is shown in cross-section in FIG. 7d. The resistor 720 is beneficially formed over the shallow-trench isolation 102 as shown, but may be formed elsewhere, including over the deep trench isolation of the semiconductor structure. The resistor is formed between contacts 721 and 722, using a doped polysilicon layer 723 (formed from a portion of polysilicon layer 601) and a silicided emitter poly layer 724 as the resistive material.

The device parameters of the semiconductor structure of FIGS. 7a-7d are both comparably excellent and well-controlled. Moreover, when compared to known methods, the SiGe BiCMOS device of the example embodiment requires only one additional masking step compared to conventional Si-BiCMOS structures, and many fewer processing steps than known SiGe fabrication methods.

Certain benefits are noteworthy and are presented here before describing additional example embodiments. These include certain typical performance characteristics and advantages of the example embodiments.

In a pnp transistor of an example embodiment, the current gain (β) is on the order of approximately 150. Moreover, in an example embodiment, the Early voltage of a pnp is 15V. A Varicap in accordance with an example embodiment has a tuning ratio: 2 (0.5V to 2.5V), and a varicap capacitance density pf 2.5 fF/um². Moreover, as can be readily appreciated from the descriptions of the example embodiments above, the lateral pnp, varicap and resistor processed using silicon processing technology are fabricated on the same wafer as the npn SiGe transistor using only one additional masking step.

The example embodiments described herein require only one extra mask-step to form varicap, lateral PNP and p+ poly resistor. Other known SiGe BiCMOS technologies use one extra maskstep to form the p+ poly resistor, another maskstep to form a varicap and yet another maskstep to form the lateral pnp transistor. Thus, the exceedingly efficient processes of the example embodiments reduce fabrication complexity and cost of manufacture.

Finally, a polyresistor fabricated according to an example embodiment has a resistance of 350 Ohm/square, a low and positive temperature coefficient 155 ppm/° C., and matching of 1.5% um.

FIG. 8 shows a semiconductor structure 800 in accordance with an example embodiment. The structure 800 includes features similar to those described thus far, but is processed by a different sequence, resulting in a SiGe npn and lateral pnp/varactor such as that described above. Initially, openings 801, 802 and 803 are formed in the salicide nitride and oxide protective layers 805 and 806, respectively. These openings may be used for the contacts to the lateral pnp and varicap formed later. Next, a silicon seed layer (not shown in FIG. 9) may be formed by standard deposition methods over the surface.

After the seed layer is formed, openings are made in the seed layer and the protective layers 805 and 806. As such, an amorphous (alpha) silicon layer is formed over the mono-silicon layers of the emitter and lateral pnp transistor and of the varicap. However, the base region of the npn transistor is not covered by the alpha-silicon.

Subsequently, poly SiGe is formed on the regions with the seed layer remaining, but not in regions where the seed layer has been removed. In these areas, and in particularly, in the region of the base of the npn transistor, monocrystalline SiGe is grown in this sequence on the monocrystalline silicon of the substrate 101.

The resultant structure is shown in FIG. 9. To with, FIG. 9 shows the lateral pnp structure, excepting the doped regions within the substrate 101, which comprise the emitter, collector and buried base regions. The structure 900 provides the emitter and first and second collector contacts 901 and 902,903, respectively. The collectors 901, 903 include a poly SiGe layer 904, 906. As is useful in improving the current gain of the device, the emitter 903 includes a poly SiGe layer 906 formed as referenced above. As before, poly Si layers 907, 908 and 909 are elements of the collector 901, emitter 903 and collector 902. Finally, it is noted that the seed layer 910 described above is disposed over the substrate 101. The seed layer 910 is deposited in an amorphous fashion at 525° C., with a thickness of 200 Angstroms. The in situ oxidation for the poly/mono interface is done at 525° C. with 90 SCCM O₂ and 90 SCCM N₃ at 260 mTorr, 30 min.

In the example embodiments of FIGS. 8 and 9, monocrystalline SiGe has a tendency to be formed on the regions of the lateral pnp emitter and varicap contacts in regions where epitaxial alignment of the seed layer. This can reduce the current gain of the lateral pnp and adversely impact the tuning range of the varicap. This issue is readily addressed by increasing the amount of interfacial oxide on the interface between the seed layer and the monocrystalline silicon. The interfacial oxide prevents direct contact of the poly silicon to the mono crystalline silicon. Poly silicon placed on monosilicon with negligible interfacial oxide is known to epitaxially align during thermal processing. We found that especially the SiGe-epi hydrogen prebake (typically at 900C for a couple of minutes) can epitaxially align the seed-layer.

The polycrystalline SiGe layer of an example embodiment can also contain carbon (SiGe:C is used for ultra high speed NPNs). The carbon in the poly will slow the boron out-diffusion from the SiGe-poly into the mono-silicon, resulting in shallow junction depth. However, there might be cases where shallow out-diffusion of dopants from a poly electrode into mono-silicon is wanted. For instance shallower diffusion of the emitter of a vertical PNP will result in shallower profiles and faster devices. In the example embodiment, forming polysilicon on monosilicon in SiGe BiCMOS, can also be used for the fabrication of poly emitters of high current gain vertical PNPs. The formation of simple polysilicon on dielectric stacks can also be advantageous for other passive devices such as capacitors.

Additionally, the lateral pnp electrical performance of an example embodiment is tailored by implanting a dedicated ‘extra’ implant after base-poly patterning into the lateral pnp base. This implant is performed after the base poly etching step, but before photoresist strip. Consequently, the resist protects the npn and varicap areas and the lateral pnp emitter and collector fingers. However the lateral pnp base is unprotected and receives the tailor implant. Also the CMOS is unprotected, but as the tailor implant dose is very low (on the order of approximately 3×10¹² cm⁻³ ) compared to the source and drain implants of the CMOS, no effects of the tailor implant on the CMOS are observed in the example embodiments.

Hence the LPNP collector current and early voltage are controlled independently of other devices in the BiCMOS flow without adding any mask steps. The tailor implant can also lower the series resistance of differential varicaps, and can be used to set the resistance of unsilicided mono-silicon resistors.

The example embodiments having been described in detail in connection through a discussion of exemplary embodiments, it is clear that modifications of the invention will be apparent to one having ordinary skill in the art having had the benefit of the present disclosure. Such modifications and variations are included in the scope of the appended claims.

What is claimed is:

1. A method of fabricating an integrated circuit, the method comprising:
providing a substrate; creating at least one base-window in a layer; forming a monocrystalline SiGe layer in at least one region, and forming a polycrystalline SiGe layer elsewhere over the substrate.

2. A method as recited in claim 1, further comprising forming a polycrystalline silicon layer over selectively exposed portions of the substrate.

3. A method as recited in claim 2, further comprising forming a mask over a top surface, providing openings in selected locations of the mask, and removing the polycrystalline silicon layer to expose the selected portions of the substrate.

4. A method as recited in claim 3, wherein the exposed portions of the substrate are monocrystalline silicon.

5. A method as recited in claim 1, wherein the integrated circuit includes a lateral pnp transistor.

6. A method as recited in claim 1, wherein the integrated circuit includes an SiGe bipolar transistor.

7. A method as recited in claim 6, wherein the SiGe bipolar transistor includes the monocrystalline SiGe.

8. A method as recited in claim 1, wherein the integrated circuit includes a varactor diode.

9. A method as recited in claim 1, further comprising forming a polysilicon resistor.

10. A method as recited in claim 1, wherein only one masking step is required to form a lateral pnp transistor, varactor diode and a polysilicon resistor.

11. A method as recited in claim 10, wherein the lateral pnp transistor is a silicon device, and includes a portion of the polycrystalline SiGe layer in each of a collector contact and an emitter contact.

12. A method as recited in claim 11, wherein the polycrystalline SiGe layer is disposed beneath a polycrystalline silicon layer.

13. A method of fabricating a semiconductor structure, the method comprising:
forming a silicon seed layer over a surface of a substrate; providing openings in the seed layer; selectively forming amorphous silicon over the substrate; and forming monocrystalline SiGe.

14. A method as recited in claim 13, further comprising, removing said amorphous silicon in regions where said monocrystalline SiGe is formed.

15. A method as recited in claim 14, wherein said removing said amorphous silicon exposes a top surface of the substrate.

16. A method as recited in claim 15, wherein the top surface is monocrystalline silicon.

17. A method as recited in claim 13, wherein the semiconductor structure includes a lateral pnp transistor.

18. A method as recited in claim 13, wherein the semiconductor structure includes a SiGe bipolar transistor.

19. A method as recited in claim 13, wherein the semiconductor structure includes a varactor diode.

20. A method as recited in claim 13, further comprising forming a polysilicon resistor.
